(19) United States
(12) Patent Application Publication
(10) Pub. No.: US 2008/0268651 A1
(43) Pub. Date: Oct. 30, 2008

(54) Catch-cup to diverter alignment leveling jig

(76) Inventors: Kent Riley Child, Los Banos, CA (US); Glen Egami, San Jose, CA (US); Alexander Sou-Kang Ko, Santa Clara, CA (US)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 11/893,183

(22) Filed: Aug. 14, 2007

Related U.S. Application Data
(60) Provisional application No. 60/838,012, filed on Aug. 15, 2006.

(51) Int. Cl. H01L 21/306; B08B 3/00

(52) U.S. Cl. 438/745; 156/345.24; 134/113; 257/E21.219

(57) ABSTRACT

An apparatus for leveling and centering a catch-cup chamber to a diverter chamber of a semiconductor processing chamber is described. In one embodiment, the apparatus has a frame with branches. A coupler is mounted to the end of each branch. A measuring device is mounted to each branch. The apparatus is placed in the diverter. The measuring device measures a distance from a branch to a top surface of the catch-cup chamber.

### RELATED APPLICATIONS

The present application claims priority from U.S. provisional patent application Ser. No. 60/838,012, filed Aug. 15, 2006.

### TECHNICAL FIELD

This invention relates to the field of semiconductor processing, and, in particular, to a support assembly.

### BACKGROUND

In semiconductor wafer substrate (wafer) cleaning, particle removal is essential. Particles can be removed by chemical means or by mechanical means. In current state of the art, particles are usually removed by both a combination of mechanical means and chemical means. The current state of the art is to immerse a wafer into a bath filled with a liquid and to apply high frequency (megasonic) irradiation to the liquid. The sonic waves travel through the liquid and provide the mechanical means to remove particles from the wafer surface. At the same time, chemicals in the liquid provide a slight surface etching and provide the right surface termination, such that once particles are dislodged from the surface by the combination of etch and mechanical action of the sonics on the particles, these particles are not redeposited on the surface. In addition, chemicals are chosen such that an electrostatic repulsion exists between the surface termination of the wafer and the particles.

Wet etching and wet cleaning of wafers is usually done by immersing the wafers into a liquid. This can also be done by spraying a liquid onto a wafer or a batch of wafers. Wet wafer cleaning and etching is traditionally done in a batch mode. Because of the need for a shorter cycle time in chip manufacturing, there is a need for fast single wafer processing. Single wafer processing is usually limited to one side of the wafer. When cleaning wafers, it is important to clean both sides of the wafers at the same time. When holding wafers, most current chucks hold the wafer with three or more supports, or use a vacuum support.

Chucks for single wafer cleaning have so far been of the type that holds the wafer on a plate, either held by vacuum or held by a N₂ cushion. These chucks do not allow double sided cleaning. Other chucks have held the wafers simply with three or more arms. The problem with these chucks is that the arms obstruct chemical spray and do not allow a brush to get to the backside of the wafer. When cleaning, it is important to have the wafer non-device side as free as possible of obstructions in order to have the wafer sides freely accessible for chemical or de-ionized water sprays and to have the wafer non-device side accessible for brushing. In addition, the arms have to move in order to clamp the wafer and the moving mechanism is exposed to chemical spray as well.

Furthermore, some of the components within a wafer processing chamber need to be concentric to each other and level.

### BRIEF DESCRIPTION OF THE DRAWINGS

The present invention is illustrated by way of example, and not by way of limitation, in the figures of the accompanying drawings.

FIG. 1 is a top perspective view of a chamber alignment tool in accordance with one embodiment.

FIG. 2 is a top perspective view of the chamber alignment tool of FIG. 1 positioned on top of a chamber in accordance with one embodiment.

FIG. 3 is a top perspective view of the chamber alignment tool of FIG. 1 engaged with a chamber in accordance with one embodiment.

FIG. 4 is a side view of a support structure within a chamber in accordance with one embodiment.

FIG. 5 is a cross-sectional perspective view of the tool of FIG. 1 engaged with a chamber in a first position.

FIG. 6 is a cross-sectional perspective view of the tool of FIG. 1 engaged with a chamber in a second position.

FIG. 7 is a cross-sectional perspective view of the tool of FIG. 1 engaged with a chamber in a third position.

FIG. 8 is a cross-sectional perspective view of the tool of FIG. 1 engaged with a chamber in a fourth position.

FIG. 9 is a flow diagram of a method for aligning a catch-cup chamber of a processing chamber in accordance with one embodiment.

### DETAILED DESCRIPTION

The following description sets forth numerous specific details such as examples of specific systems, components, methods, and so forth, in order to provide a good understanding of several embodiments of the present invention. It will be apparent to one skilled in the art, however, that at least some embodiments of the present invention may be practiced without these specific details. In other instances, well-known components or methods are not described in detail or are presented in simple block diagram format in order to avoid unnecessarily obscuring the present invention. Thus, the specific details set forth are merely exemplary. Particular implementations may vary from these exemplary details and still be contemplated to be within the spirit and scope of the present invention.

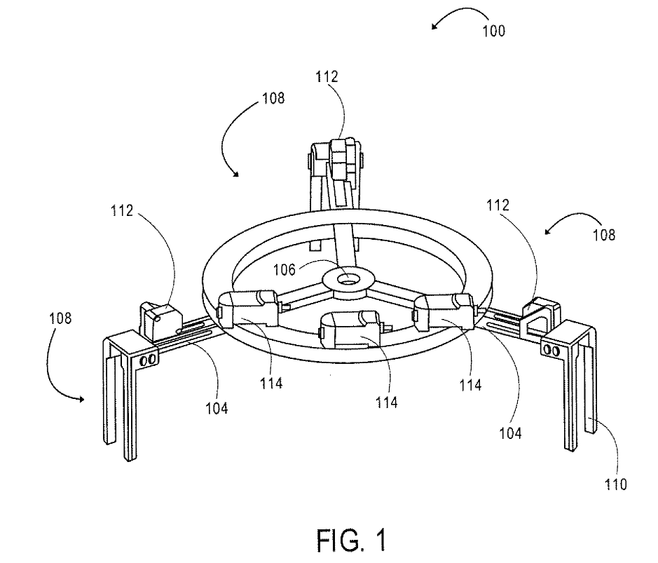

FIG. 1 is a top perspective view of a chamber alignment tool 100 in accordance with one embodiment. The tool 100 may be used to align a catch-cup chamber to a diverter chamber of a semiconductor processing apparatus. The tool 100 may include a frame 102, three forks, three amplifiers, three laser heads, and three brackets.

The frame 102 may be a disk or a ring having at least three branches 104 extending radially outward from its center 106. Each branch 104 may have the same length. The branches 104 may be angularly equidistant. For example, with three branches, each branch 104 may be 120 degrees separated from the next branch 104. The frame 102 may be made of a material suitable for the chamber.

In accordance with another embodiment, a level (not shown) may be placed in the center of the disk as a means for leveling the frame. Those of ordinary skills in the art will recognize that there are other means for leveling the disk.

A fork 108 may be coupled to the end of each branch 104. Each fork 108 may have at least two prongs 110 to couple with a component of the chamber. The prongs 110 may be aligned along an axis substantially perpendicular to the plane formed by the frame 102 and the branches 104. Screws may couple the forks 108 to their respective branches 104.

A distance measuring device 12, such as a laser head, may be attached to each branch 104. Other measuring devices may be used such as, for example, ultrasound, or digital/analog dial micrometer. The laser head 112 may be placed adjacent to the fork 108 and may be directing a laser beam along an axis substantially perpendicular to the plane of the frame 102. The laser head 112 may be mounted to each branch 104 of the frame 102 with a bracket. The laser head 112 measures the distance of each branch 104 to a component of the chamber positioned below the tool 100.

Each laser head 112 may be electrically connected to a respective amplifier 114 for reading out the measured distance. The amplifiers 114 may be mounted to the frame 102 of the tool 100. The laser head 112 measures the distance of each branch 104 to a component of the chamber positioned below the tool.

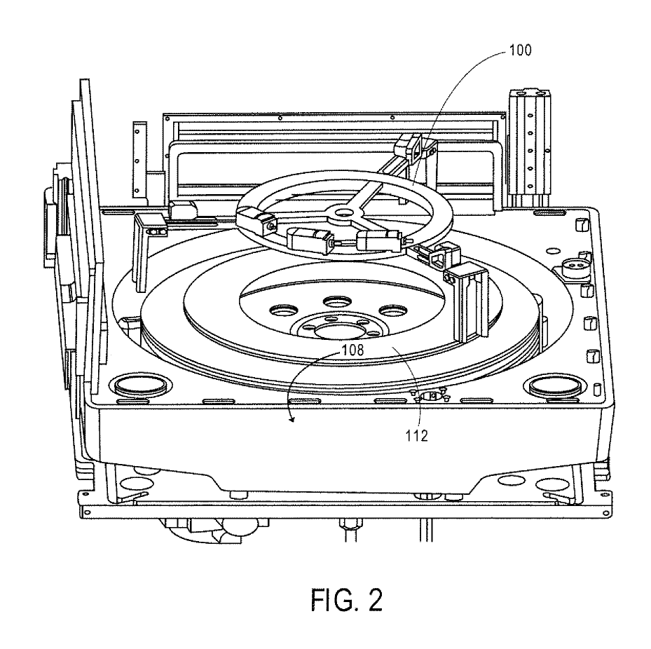

FIG. 2 is a top perspective view of the chamber alignment tool of FIG. 1 positioned on top of a chamber in accordance with one embodiment. The tool is about to be engaged with components within the chamber. A rinse cap is removed. The catch-cups are lowered to their lowest position. The labyrinth seals bottomed out on the chamber bowel bottom for the first position. As illustrated in FIG. 2, the tool is positioned above the diverter and the catch-cups in the chamber.

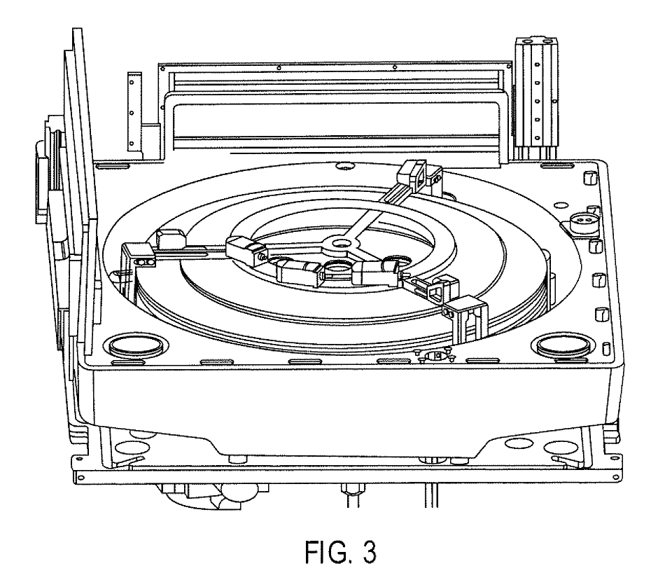

FIG. 3 is a top perspective view of the chamber alignment tool of FIG. 1 engaged with a chamber in accordance with one embodiment. The tool is placed over and down into the diverter. The tool rests on the inside lip of the diverter. The three branches are straddling the three labyrinth seals on the catch-cup. The laser amplifiers may be positioned so that they are facing the front of the tool for easier readout.

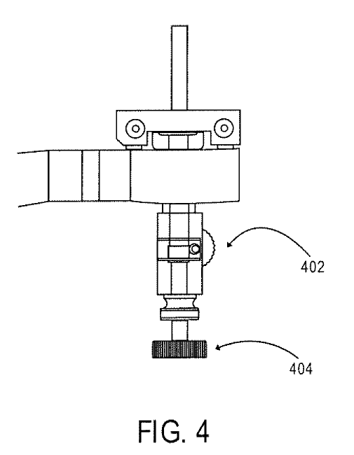

Each fork mates its respective lift post from the catch-cup. The lift posts are secured to a base plate of the chamber. The height of the lift posts may be adjusted as illustrated in FIG. 4. The catch-cup alignment adjusters 402 are loosened so that the catch-cup assembly is constrained with the straddle points on the alignment jig/tool. The alignment jig/tool may be set flat and concentric with the diverter. The catch-cups are adjusted until the tool is level flat and concentric with the diverter.

The lift mechanism side is tightened to side adjusters. The catch-cups are now centered on the diverter. The leveling screws 404 on catch-cup lift mechanism are adjusted so that all three lasers are reading the same number. When the numbers are all equal, the catch-cups are then level to the diverter. All lift adjustments are then tightened.

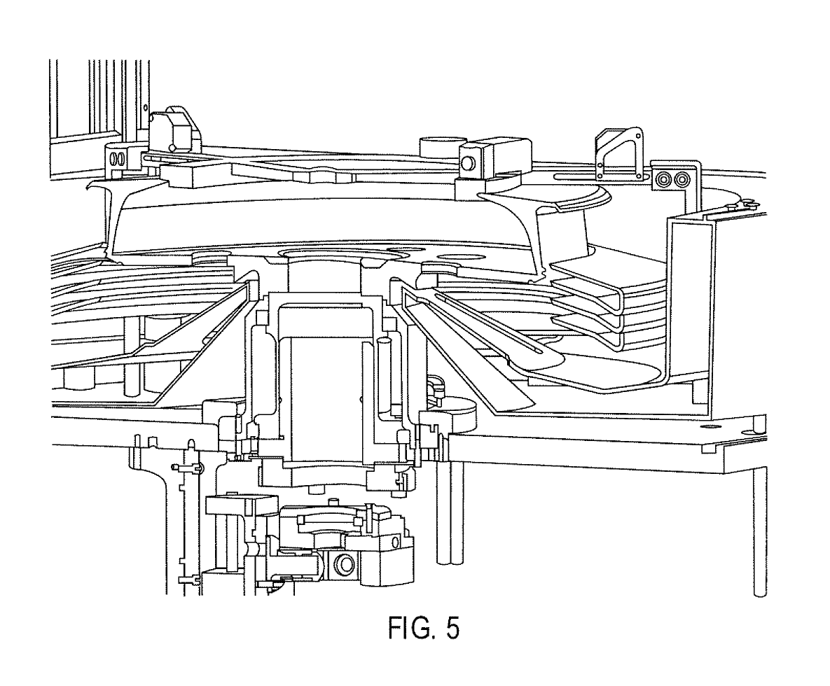

FIG. 5 is a cross-sectional perspective view of the tool of FIG. 1 engaged with a chamber in a first position. A computer may be connected the chamber and/or the laser heads. Once the catch-cup is level and centered with the diverter, and the catch-cup is positioned so that a first cup chamber is adjacent to a diverter slit, this position may be set as position one. A software in the computer may be used to associate the readout of the laser heads with position one.

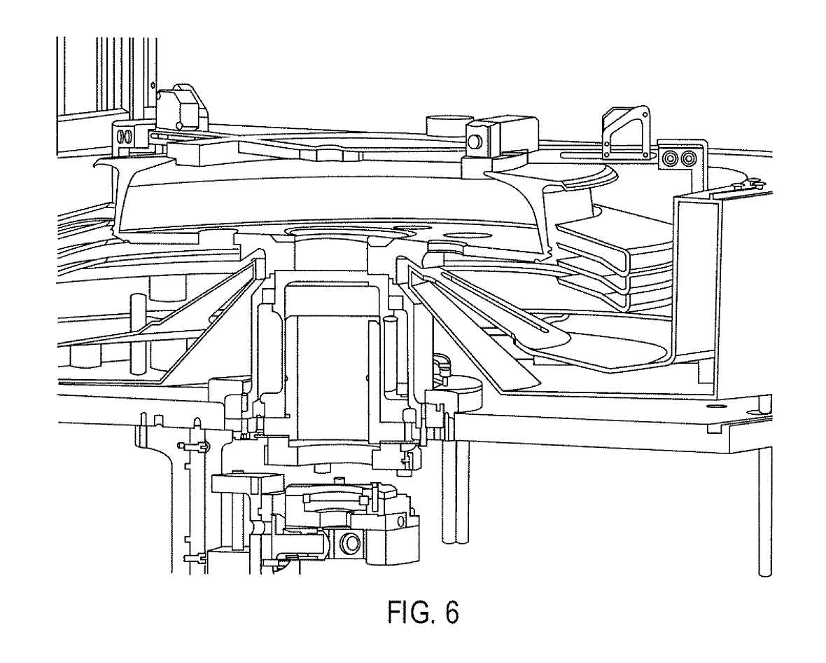

The height difference between each catch-cup chamber is already preset and thus by moving the catch-cup up by the preset height, the next catch-cup chamber is adjacent to the diverter slit. FIG. 6 is a cross-sectional perspective view of the tool of FIG. 1 engaged with the chamber wherein the catch-cup is in a second position. The software of the computer may set this as position two.

In accordance with another embodiment, the software may move the catch-cup up until a pre-determined height is shown on the laser head. The software may be reset to remember this position as position two.

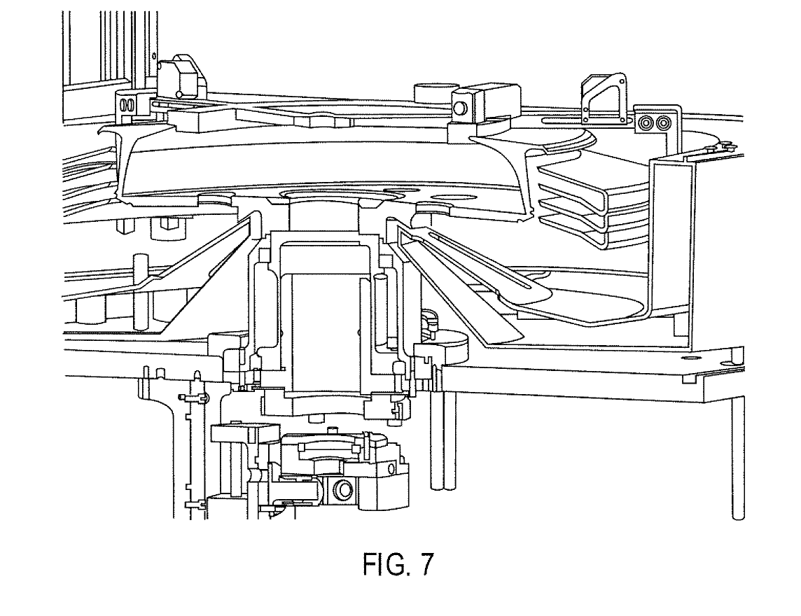

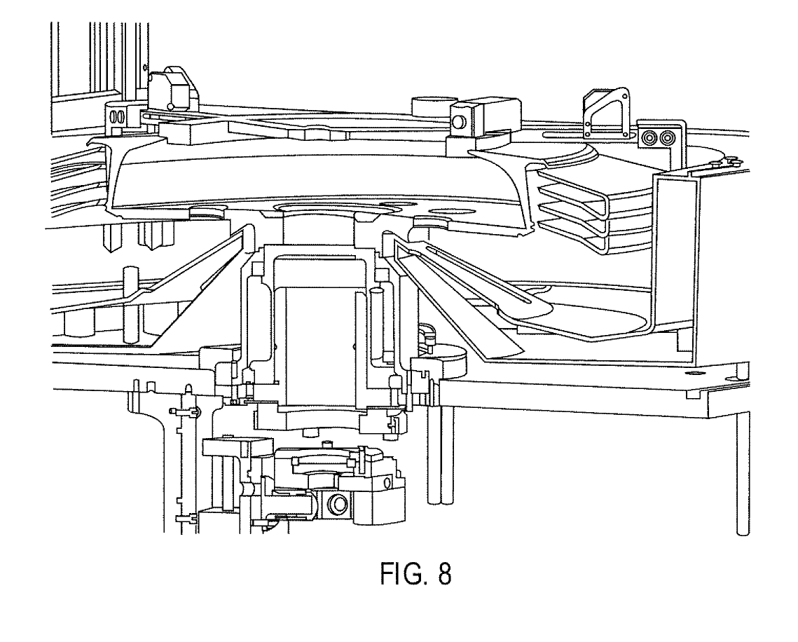

FIG. 7 is a cross-sectional perspective view of the tool of FIG. 1 engaged with a chamber in a third position. FIG. 8 is a cross-sectional perspective view of the tool of FIG. 1 engaged with a chamber in a fourth position. Those of ordinary skills in the art will recognize that there may be more or less catch-cup chambers than the three catch-cup chambers presently illustrated.

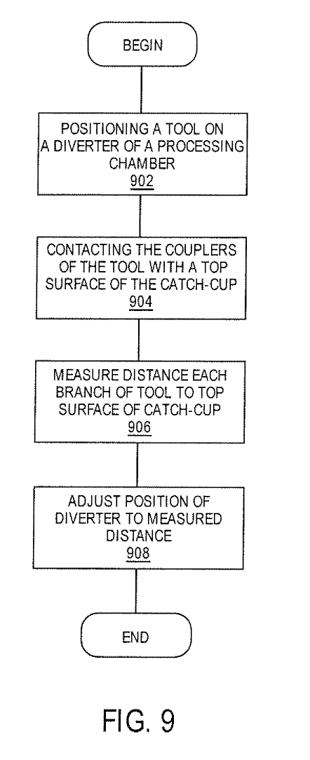

FIG. 9 is a flow diagram illustrating a method for centering and leveling a catch-up chamber of a semiconductor processing chamber. At 902, a tool is placed on a lip of a diverter of the chamber. The tool includes a frame having a plurality of branches, a plurality of couplers corresponding to the plurality of branches. Each coupler may be mounted to the end of each branch. The tool may also include a plurality of measuring devices corresponding to the plurality of branches. Each measuring device may be mounted to each branch.

At 904, the couplers may come in contact with a top surface of the catch-cup of the chamber. A distance of each branch of the tool to the top surface of the catch-cup is measured with the measuring devices. A position of the catch-up is adjusted with respect to the diverter in response to the measured distances.

Although the operations of the method(s) herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative sense rather than a restrictive sense.

What is claimed is:

1. An apparatus for leveling and centering a component within a semiconductor processing chamber comprising:
a frame having a plurality of branches;
a plurality of couplers corresponding to the plurality of branches, each coupler mounted to the end of each branch; and
a plurality of measuring devices corresponding to the plurality of branches, each measuring device mounted to each branch.

2. The apparatus of claim 1, wherein the frame includes a disk.

3. The apparatus of claim 2, wherein each branch extends radially outside the disk.

4. The apparatus of claim 3, wherein each branch has the same length.

5. The apparatus of claim 4, wherein each branch is angularly equidistant to each other.

6. The apparatus of claim 5, further comprising a level positioned at the center of the disk.

7. The apparatus of claim 1, wherein the coupler includes a fork having two prongs, each prong extending along an axis normal to the plane formed by the frame.

8. The apparatus of claim 1, wherein the fork is to mate with a pin of a base plate of a semiconductor processing chamber.

9. The apparatus of claim 1, wherein the frame is to rest on a lid of a diverter of a semiconductor processing chamber.

10. The apparatus of claim 1, wherein each measuring device includes a laser measuring device.

11. The apparatus of claim 10, further comprising a plurality of laser amplifiers, each laser amplifier corresponding to a laser measuring device, the laser amplifiers displaying a measurement performed by the laser measuring devices.

12. The apparatus of claim 1, wherein the laser measuring device measures a distance from the branch to a top surface of a catch-cup chamber.

13. The apparatus of claim 12, wherein a portion of the top surface of the catch-cup chamber is parallel to the plane formed by the frame.

14. A method for centering and leveling a catch-up to a diverter of a semiconductor processing chamber, the method comprising:
positioning a tool on a lip of the diverter of the chamber, the tool having a frame having a plurality of branches, a plurality of couplers corresponding to the plurality of branches, each coupler mounted to the end of each branch, and a plurality of measuring devices corresponding to the plurality of branches, each measuring device mounted to each branch.
contacting the couplers a top surface of the catch-cup of the chamber;
measuring a distance of each branch of the tool to the top surface of the catch-cup with the measuring devices; and
adjusting a position of the catch-up with respect to the diverter in response to the measured distances.

15. The method of claim 14, wherein the frame includes a disk.

16. The method of claim 15, wherein each branch extends radially outside the disk.

17. The method of claim 16, wherein each branch has the same length.

18. The method of claim 17, wherein each branch is angularly equidistant to each other.

19. The method of claim 18, further comprising:
leveling the tool with a level positioned at the center of the frame.

20. The method of claim 14, further comprising:
leveling the position of the catch-cup so that a portion of the top surface of the catch-cup is parallel to the plane formed by the frame.
